(19) United States
(12) Patent Application Publication
(10) Pub. No.: US 2026/0142675 A1
(43) Pub. Date: May 21, 2026

(54) MULTI-CANDIDATE SUCCESSIVE CANCELLATION LIST DECODING OF POLAR CODES

(71) Applicant: Apple Inc., Cupertino, CA (US)

(72) Inventors: Arman Fazeli Chaghooshi, Redwood City, CA (US); Daniel Kern, Munich (DE); Joan Anton Olivella Munne, Munich (DE); Louay Jalloul, San Jose, CA (US); Mohamad Mansour, San Jose, CA (US); Onurcan Iscan, Munich (DE)

(73) Assignee: Apple Inc., Cupertino, CA (US)

(21) Appl. No.: 18/949,944

(22) Filed: Nov. 15, 2024

(51) Int. Cl. H03M 13/45; H03M 13/09; H04L 1/00; H04W 72/231

(52) U.S. Cl. CPC H03M 13/453; H03M 13/09; H04L 1/0038; H04W 72/231

(57) ABSTRACT

The present application relates to multi-candidate successive cancellation list (SCL) decoding of polar codes. In an example, an apparatus processes multiple candidate codewords using a same SCL decoder. The SCL decoder may be cyclic redundancy code (CRC)-aided. The multiple candidate codewords may have different code configurations and/or different inputs. In an example, the multiple candidate codewords are packaged so that at most one of the candidate codewords in the package is valid.

### BACKGROUND

In Third Generation Partnership (3GPP) New Radio (NR), polar codes are used for error correction coding of physical downlink control channel (PDCCH). A user equipment (UE) is expected to blindly decode multiple PDCCH candidates to find the PDCCH candidates that include valid downlink control information (DCI) (e.g., DCI intended for the UE). Most polar decoding schemes are sequential and require relatively long decoding times. Multi-threaded architectures include multiple decoders to decode respective PDCCH candidates in parallel. However, these architectures require additional chip area and do not improve power consumption.

### BRIEF DESCRIPTION OF THE DRAWINGS

FIG. 1 illustrates an example of a network environment in accordance with some embodiments.

FIG. 2 illustrates an example system for communication including a transmit chain and a receive chain, in accordance with some embodiments.

FIG. 3 illustrates components of a system in accordance with some embodiments.

FIGS. 4A-4F illustrate a binary decision tree to process multiple candidate codewords, in accordance with some embodiments.

FIG. 5 illustrates performance examples of multi-candidate successive cancellation list decoding in accordance with some embodiments.

FIG. 6 illustrates other performance examples of multi-candidate successive cancellation list decoding in accordance with some embodiments.

FIG. 7 illustrates other performance examples of multi-candidate successive cancellation list decoding in accordance with some embodiments.

FIG. 8 illustrates an example of an operational flow/algorithmic structure for multi-candidate successive cancellation list decoding in accordance with some embodiments.

FIG. 9 illustrates another example of an operational flow/algorithmic structure for multi-candidate successive cancellation list decoding in accordance with some embodiments.

FIG. 10 illustrates another example of an operational flow/algorithmic structure for multi-candidate successive cancellation list decoding in accordance with some embodiments.

FIG. 11 illustrates an example of receive components in accordance with some embodiments.

FIG. 12 illustrates an example of a UE in accordance with some embodiments.

FIG. 13 illustrates an example of a base station in accordance with some embodiments.

### DETAILED DESCRIPTION

Embodiments of the present disclosure relate to, among other things, batch dynamic successive cancellation flip decoding of polar codes. In an example, a user equipment (e.g., a modulator/demodulator (modem) thereof) processes information received from a base station. The processing includes decoding candidate codewords. A candidate codeword can correspond to information (e.g., control information) that the base station encodes using particular error correction codes (e.g., polar codes). The processing can include attempting to decode the candidate codewords such that, in case of a decoding success, one or more codewords are successfully decoded and the relevant information is determined. The decoding can use a multi-candidate successive cancellation list (SCL) decoding procedure. In an example, an apparatus processes multiple candidate codewords using a same SCL decoder. The SCL decoder may be cyclic redundancy code (CRC)-aided. The multiple candidate codewords may correspond to any suitable decoding candidates (e.g., blind decoding candidates), such as physical downlink control channel (PDCCH) candidates and/or physical broadcast channel (PBCH) candidates. The candidate codewords may have different code configurations (e.g., formats, such as downlink control information (DCI) formats in the case of PDCCH candidates) and/or different inputs (e.g., log-likelihood ratio (LLR) inputs). In an example, the multiple candidate codewords are packaged so that at most one of the candidate codewords in the package is valid (e.g., includes valid DCI or is a valid PBCH). The multi-candidate SCL decoding procedure may reduce power consumption and/or improve performance compared with decoding the candidate codewords using respective individual decoders.

In the interest of clarity of explanation, various embodiments are described in connection with codewords that encode DCI and with blind DCI decoding. However, the embodiments are not limited as such and can similarly and equivalently apply to decoding other types of information, such as PBCH and/or other suitable decoding candidates. Such information can be stored in a memory (e.g., in the use case of data storage) and/or can be transmitted (e.g., between a base station and a UE).

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc. in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrase “A or B” means (A), (B), or (A and B).

The following is a glossary of terms that may be used in this disclosure.

The term “circuitry” as used herein refers to, is part of, or includes hardware components, such as an electronic circuit, a logic circuit, a processor (shared, dedicated, or group) or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, a programmable system-on-a-chip (SoC)), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” “or “processing circuitry” as used herein refers to, is part of, or includes circuitry capable of sequentially and automatically carrying out a sequence of arithmetic or logical operations, or recording, storing, or transferring digital data. The term “processor circuitry” and “processing circuitry” may refer to an application processor, baseband processor, a central processing unit (CPU), a graphics processing unit, a single-core processor, a dual-core processor, a triple-core processor, a quad-core processor, or any other device capable of executing or otherwise operating computer-executable instructions, such as program code, software modules, or functional processes.

The term “interface circuitry” as used herein refers to, is part of, or includes circuitry that enables the exchange of information between two or more components or devices. The term “interface circuitry” may refer to one or more hardware interfaces, for example, buses, I/O interfaces, peripheral component interfaces, network interface cards, or the like.

The term “user equipment” or “UE” as used herein refers to a device with radio communication capabilities and may describe a remote user of network resources in a communications network. The term “user equipment” or “UE” may be considered synonymous to, and may be referred to as, client, device, mobile, mobile device, mobile terminal, user terminal, mobile unit, mobile station, mobile user, subscriber, user, remote station, access agent, user agent, receiver, radio equipment, reconfigurable radio equipment, reconfigurable mobile device, etc. Furthermore, the term “user equipment” or “UE” may include any type of wireless/wired device or any computing device including a wireless communications interface. The UE may have a primary function of communication with another UE or a network and the UE may be integrated with other devices and/or systems (e.g., in a vehicle).

The term “base station” as used herein refers to a device with radio communication capabilities, that is a device of a communications network (or, more briefly, network), and that may be configured as an access node in the communications network. A UE's access to the communications network may be managed at least in part by the base station, whereby the UE connects with the base station to access the communications network. Depending on the radio access technology (RAT), the base station can be referred to as a gNodeB (gNB), eNodeB (eNB), access point, repeater on a communications satellite, etc.

The term “channel” as used herein refers to any transmission medium, either tangible or intangible, which is used to communicate data or a data stream. The term “channel” may be synonymous with or equivalent to “communications channel,” “data communications channel,” “transmission channel,” “data transmission channel,” “access channel,” “data access channel,” “link,” “data link,” “carrier,” “radio-frequency carrier,” or any other like term denoting a pathway or medium through which data is communicated. Additionally, the term “link” as used herein refers to a connection between two devices for the purpose of transmitting and receiving information.

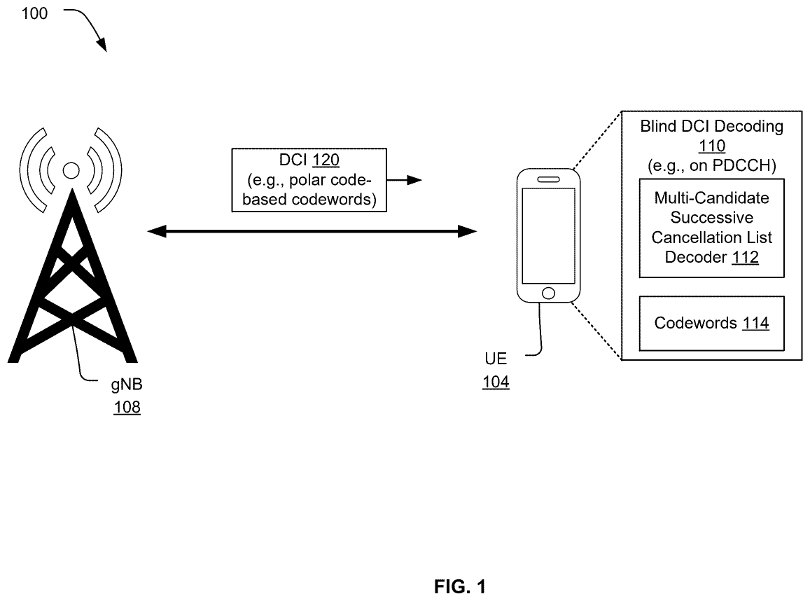

FIG. 1 illustrates a network environment 100, in accordance with some embodiments. The network environment 100 may include a UE 104 and a base station 108. The base station 108 provides a wireless access cell; for example, a Third-Generation Partnership Project (3GPP) New Radio (NR) cell, through which the UE 104 may communicate with the gNB. The base station 108 may include a set of transmission and reception points (TRPs). The UE 104 and the base station 108 may communicate over an interface compatible with 3GPP technical specifications, such as those that define Fifth-Generation (5G) NR system standards, Sixth-Generation (6G) standards, or the like.

The base station 108 may transmit information (for example, data and control signaling) in the downlink direction by mapping logical channels on the transport channels, then transport channels onto physical channels. The logical channels may transfer data between a radio link control (RLC) and media access control (MAC) layers; the transport channels may transfer data between the MAC and PHY layers; and the physical channels may transfer information across the air interface. The physical channels may include a physical broadcast channel (PBCH); a physical downlink control channel (PDCCH); and a physical downlink shared channel (PDSCH).

The PBCH may be used to broadcast system information that the UE 104 may use for initial access to a serving cell. The PBCH may be transmitted along with physical synchronization signals (PSS) and secondary synchronization signals (SSS) in a synchronization signal (SS)/PBCH block. The SS/PBCH blocks (SSBs) may be used by the UE 104 during a cell search procedure and for beam selection.

The PDSCH may be used to transfer end-user application data, signaling radio bearer (SRB) messages, system information messages (other than, for example, MIB), and paging messages.

The PDCCH may transfer downlink control information (DCI) that is used by a scheduler of the base station 108 to allocate both uplink and downlink resources. The DCI may also be used to provide uplink power control commands, configure a slot format, or indicate that preemption has occurred.

The base station 108 may also transmit various reference signals to the UE 104. The reference signals may include demodulation reference signals (DMRSs) for the PBCH, PDCCH, and PDSCH. The UE 104 may compare a received version of the DMRS with a known DMRS sequence that was transmitted to estimate an impact of the propagation channel. The UE 104 may then apply an inverse of the propagation channel during a demodulation process of a corresponding physical channel transmission.

The reference signals may also include a CSI reference signal (CSI-RS). The CSI-RS may be a multi-purpose downlink transmission signal that may be used for CSI reporting, beam management, connected mode mobility, radio link failure detection, beam failure detection and recovery, and fine-tuning of time and frequency synchronization.

The reference signals and information from the physical channels may be mapped to resources of a resource grid. There is one resource grid for a given antenna port, subcarrier spacing configuration, and transmission direction (for example, downlink or uplink). The basic unit of an NR downlink resource grid may be a resource element, which may be defined by one subcarrier in the frequency domain, and one orthogonal frequency division multiplexing (OFDM) symbol in the time domain. Twelve consecutive subcarriers in the frequency domain may compose a physical resource block (PRB). A resource element group (REG) may include one PRB in the frequency domain, and one OFDM symbol in the time domain, for example, twelve resource elements. A control channel element (CCE) may represent a group of resources used to transmit PDCCH. One CCE may be mapped to a number of REGs; for example, six REGs.

Transmissions that use different antenna ports may experience different radio channels. However, in some situations, different antenna ports may share common radio channel characteristics. For example, different antenna ports may have similar Doppler shifts, Doppler spreads, average delay, delay spread, or spatial receive parameters (for example, properties associated with a downlink received signal angle of arrival at a UE). Antenna ports that share one or more of these large-scale radio channel characteristics may be said to be quasi co-located (QCL) with one another. 3GPP has specified four types of QCL to indicate which particular channel characteristics are shared. In QCL Type A, antenna ports share Doppler shift, Doppler spread, average delay, and delay spread. In QCL Type B, antenna ports share Doppler shift and Doppler spread. In QCL Type C, antenna ports share Doppler shift and average delay. In QCL Type D, antenna ports share spatial receiver parameters.

The base station 108 may provide transmission configuration indicator (TCI) state information to the UE 104 to indicate QCL relationships between antenna ports used for reference signals (for example, synchronization signal/PBCH or CSI-RS) and downlink data or control signaling (for example, PDSCH or PDCCH). The base station 108 may use a combination of RRC signaling, MAC control element signaling, and DCI, to inform the UE 104 of these QCL relationships.

The UE 104 may transmit data and control information to the base station 108 using physical uplink channels. Different types of physical uplink channels are possible, including a physical uplink control channel (PUCCH) and a physical uplink shared channel (PUSCH). Whereas the PUCCH carries control information from the UE 104 to the base station 108, such as uplink control information (UCI), the PUSCH carries data traffic (e.g., end-user application data) and can carry UCI.

In an example, communications with the base station 108 can use channels in the frequency range 1 (FR1) band and/or frequency range 2 (FR2) band, although other frequency ranges are possible. The FR1 band includes a licensed band and an unlicensed band. The NR unlicensed band (NR-U) includes a frequency spectrum that is shared with other types of radio access technologies (RATs) (e.g., LTE-LAA, WiFi, etc.). A listen-before-talk (LBT) procedure can be used to avoid or minimize collision between the different RATs in the NR-U, whereby a device applies a clear channel assessment (CCA) check before using the channel.

The UE 104 can be located within a network coverage. In particular, the base station 108 may provide the network coverage with signaling (e.g., which may be carried by one or more beams). The network coverage may represent a cell or a portion of the cell that the base station 108 provides. The network coverage may provide network connections to multiple UEs, similar to the UE 104. These UEs may communicate with the base station 108 on both the uplink and the downlink based on channels available to them when the UEs are in the network coverage.

In an example, the UE 104 supports carrier aggregation (CA), whereby the UE 104 can connect and exchange data simultaneously over multiple component carriers (CCs) with the base station 108. The CCs can belong to the same frequency band, in which case they are referred to as intra-band CCs. Intra-band CCs can be contiguous or non-contiguous. The CCs can also belong to different frequency bands, in which case they are referred to as inter-band CCs. A serving cell can be configured for the UE 104 to use a CC. A serving cell can be a primary (PCell), a primary secondary cell (PSCell), or a secondary cell (SCell). Multiple SCells can be activated via an SCell activation procedures where the component carriers of these serving cells can be intra-band contiguous, intra-band noon-contiguous, or inter-band. The serving cells can be collocated or non-collocated.

The UE 104 can also support dual connectivity (DC), where it can simultaneously transmit and receive data on multiple CCs from two serving nodes or cell groups (a master node (MN) and a secondary node (SN)). DC capability can be used with two serving nodes operating in the same RAT or in different RATs (e.g., an MN operating in NR, while an SN operates in LTE). These different DC modes include, for instance, evolved-universal terrestrial radio access-new radio (EN)-DC, NR-DC, and NE-DC (the MN is a NR gNB and the SN is an LTE eNB).

As further described in connection with the next figures, the base station 108 can send DCI 120 in PDCCH to the UE 104. The UE 104 can perform blind DCI decoding 110 on the PDCCH to determine the DCI 120.

In one example, the base station 120 (e.g., an RF transmit chain thereof, or a component of this chain such as an encoder) encodes the DCI 120 using an encoding algorithm (e.g., one for polar codes). Accordingly, the actual signals that are transmitted represent one or more codewords that encode the DCI 120 and that enable error detection and correction at the UE 104.

The UE 104 (e.g., an RF receive chain thereof) can receive and process the signals. Due to noise, interference, and other signals, errors may have been introduced in the transmission and/or reception. The processing can include decoding candidate codewords (e.g., detected blocks of information that correspond to the codewords and that may include errors) to correct, if possible, the errors, decode the one or more codewords (shown as codewords 114 upon the decoding), and accordingly determine the DCI 120 based on the codewords 114. The decoding can be implemented by a multi-candidate successive cancellation list (SCL) decoder 112 (e.g., a cyclic redundancy check (CRC)-aided multi-candidate SCL decoder) as further described herein.

While embodiments are described with respect to blind decoding of PDCCH candidates by a UE, the disclosed embodiments may also be used for decoding other types of signals, such as PBCH and/or other physical channels or signals. Additionally, in some embodiments, the base station may include one or more multi-candidate SCL decoders to decode uplink transmissions from the UE and/or other devices.

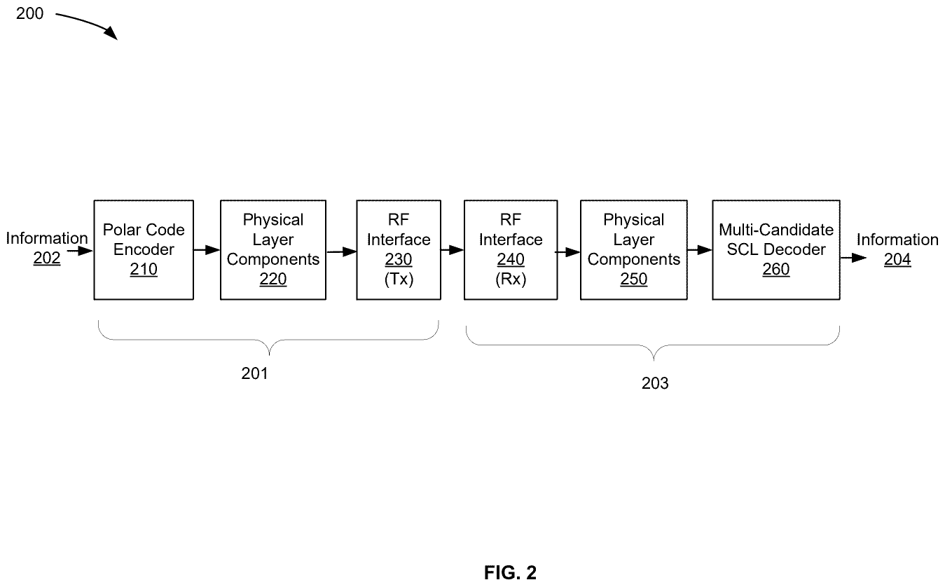

FIG. 2 illustrates examples of a system 200 for communication in accordance with some embodiments. As illustrated, the system 200 includes a transmit chain 201 and a receive chain 203 for a transmission path (e.g., a downlink transmission path). The transmit chain 201 can be included in a radio frequency front end of a base station for processing information 202 (including DCI) and transmitting signals that represent the information 202 to UEs. The receive chain 203 can be included in a radio frequency front end of a UE for receiving and processing such signals to determine information 204. Equivalently for an uplink path, a similar transmit chain can be included in the UE (e.g., for transmitting UCI or other information) and a similar receive chain can be included in the base station (e.g., for receiving such information).

Error detection and/or correction can be implemented such that the information 204 is the same as the information 202 or any resulting error rate is smaller than an acceptable threshold error rate. To do so, the transmit chain 201 can include a polar code encoder 210, whereas the receive chain can include a multi-candidate SCL decoder 260.

In an example, the polar code encoder 210 can process bits that represent the information 202 at a block level (e.g., in information blocks). Bits that represent an information block can be encoded using polar codes to generate one or more codewords. The generated codewords can be passed to physical layer components 220 of the transmit chain 201, such as a scrambler, a modulator, a precoder, and/or a resource element mapper, such that the codewords can be modulated and mapped onto resource elements. An RF interface 230 of the transmit (Tx) chain (e.g., a transmitter coupled with a set of antennas) can then output the corresponding signals.

The signals can be received by an RF interface 240 of the receive (Rx) chain 203 (e.g., a receiver coupled with a set of antennas). Following a set of operations (e.g., amplifying, frequency shifting, filtering, analog to digital conversion, etc.), physical layer components 250 of the receive chain (e.g., descrambler, demodulator, etc.) can output candidate codewords to the multi-candidate SCL decoder 260 that in turn decodes the candidate codewords and, if the decoding is successful, can output bits that represent the information 204.

In an example, the information 202 includes DCI. The multi-candidate SCL decoder 260 can be used for DCI blind decoding. In this case, the multi-candidate SCL decoder may support up to a specified maximum number of candidate codewords. For example, in a 5G NR system, the maximum number may be 44 for Frequency Range 1 (FR1) and 20 for Frequency Range 2 (FR2).

In an example, the input to the multi-candidate SCL decoder 260 includes multiple candidate codewords. The candidate codewords may include soft bits and/or hard bits. A soft bit can represent a binary value (e.g., a one or zero) and a likelihood of that value to be correct (e.g., a log likelihood ratio (LLR)). A group of soft bits can correspond to a symbol (which may depend on the modulation technique). The output of the multi-candidate SCL decoder 260 can be a hard decoding decision: a binary value (e.g., a one or a zero) for each bit if the decoding is successful.

To illustrate an example of polar encoding, the vector x denotes the binary polar coded vector and y denotes the received signal disrupted by noise. The uncoded bits are denoted by u₁, u₂, . . . , uₖ, which may or may not be pre-coded with a CRC code. A polar encoding transformation may be applied to the uncoded bits by multiplying the vector u by a k×n matrix, where n is a power of 2 (e.g., n=2^{m}). The transformation matrix is derived by removing n−k rows from an n×n polar generator matrix (G), for example:

$$G = {[ \begin{matrix}1 & 0 \\ 1 & 1\end{matrix} ]}^{{⊗}_{m}} ,$$

where ⊗ is the Kronecker multiplication and the rows are selected according to a polar construction that is referred to as the frozen bit mapping. The polar construction may be optimized for (n, k) and/or the channel parameters. It is possible to define the encoding transformation in a more generic way that is suitable for a variety of frozen bit mappings without significant hardware change. For example, a length-n binary vector v may be formed by inserting n−k zeros in between the uᵢ's according to the frozen bit mapping and then multiply the full-length vector by the n×n matrix without removing any of its rows. This convention may be used for describing various embodiments herein, since all of the vi bits become useful during the decoding.

The input to the decoder includes a length-n vector of soft bits (e.g., LLRs) denoted by the vector [symbol] = [symbol] ₁, [symbol] ₂, . . . , [symbol] ₙ.

Successive cancellation (SC) decoding was developed to decode polar codes. The SC decoding technique decodes bits vi of the vector one-by-one in a sequential manner. For example, the decoder at step i computes a likelihood for vi (denoted as a (\hat{ν}ᵢ)), which can be formulated as:

$$α ( {\hat{v}}_{i} ) = log ( \frac{w ( y , {\hat{v}}_{1}^{i - 1} \vert {\hat{v}}_{i} = 0 )}{w ( y , {\hat{v}}_{1}^{i - 1} \vert {\hat{v}}_{i} = 1 )} ) .$$

The hard decision is made according to the following rule:

$${\hat{v}}_{i} = \{ \begin{matrix}0 & if α > 0 or {u}_{i} is frozen \\ 1 & otherwise\end{matrix} .$$

A flaw of SC decoding is error propagation. Once a bit is incorrectly decoded, there is no mechanism to fix it in later stages. SCL decoding was developed to address this issue. In SCL decoding, a list of multiple decoding candidates is maintained. For example, the SCL decoder may store and pursue up to L candidate paths, where L is referred to as the list size. A path metric is computed for each path, and their extensions, throughout the decoding process. At each bit position, the paths with the best path metrics (e.g., up to L paths) are maintained and the other paths are discarded. The path metric utilizes the computed soft bits (e.g., including information bits and frozen bits) up to that point. An example path metric for vⱼ at decoding step j can be formulated as:

$$log [ P ( {\hat{v}}_{1}^{j} = {v}_{1}^{j} \vert {y}_{1}^{n} ) ] = - {\sum }_{i = 1}^{j} log [ 1 + exp [ 2 {\hat{v}}_{i} - 1 ) α ( {\hat{v}}_{i} ) ] ] .$$

Upon completion of the decoding, a total of L paths have been computed, with each path corresponding to a candidate codeword. The SCL decoder can declare the candidate codeword corresponding to the path with the largest path metric as the output. Larger values of L yield a better error recovery since there is a higher chance of maintaining the correct codeword in the list. However, numerical results indicate that a SCL decoder with a moderate value of L (e.g., 2, 4, 8, etc.) can perform nearly as well as a maximum likelihood (ML) decoder.

In some instances, the information bits may be precoded with a CRC. The SCL decoder may perform a CRC check on the candidate codewords for each path at the end of the decoding process. Any paths that do not pass the CRC check are eliminated from consideration. Accordingly, the CRC-aided SCL decoder (also referred to as a CA-SCL decoder) can select the candidate codeword that corresponds to the path with the largest path metric that passes the CRC check as the output. CRC-aided SCL has been demonstrated to have superior performance over a conventional polar decoder.

Blind decoding for PDCCH requires the UE to decode the control information without prior knowledge of its exact location (e.g., resources) and/or DCI format. The DCI formats vary and can be used to specify different types of control information (e.g., scheduling grants, control information, etc.). The UE is expected to decode potential DCI candidates from multiple PDCCH candidates across various aggregation levels and search spaces. The PDCCH candidates may vary in their code length, code rate, and/or frozen bit mapping.

Typically, separate instances of the polar decoder are used to decode individual PDCCH candidates. Given the number of PDCCH candidates that must be monitored, this leads to significant power consumption and decoder circuit area. Embodiments herein provide a multi-candidate SCL decoder that may decode multiple candidates simultaneously while providing overall reliability and efficiency of the communication system. The multi-candidate SCL decoder may provide decreased power consumption compared to prior techniques. Additionally, or alternatively, the candidate SCL decoder may enable the UE to include fewer instances of the decoder and/or increased throughput (e.g., number of PDCCH candidates that can be monitored).

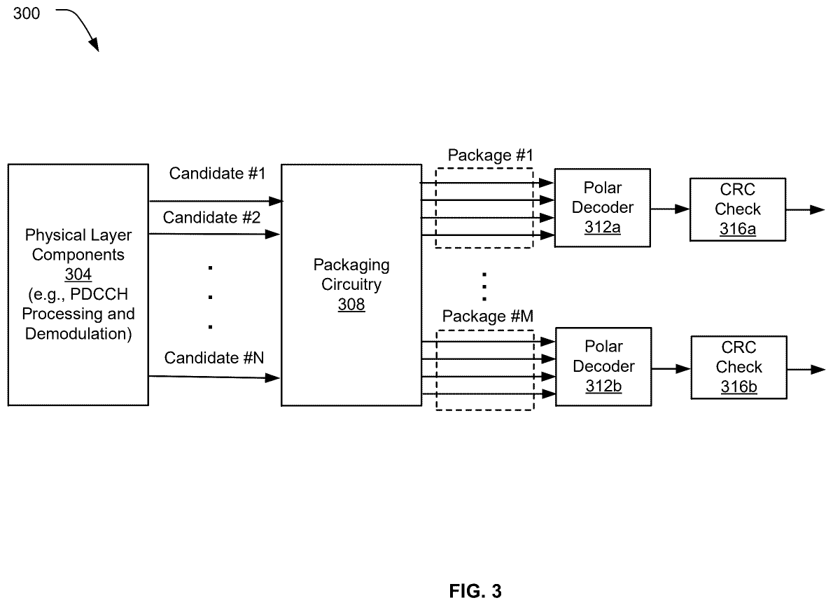

FIG. 3 illustrates example components of a system 300 in accordance with some embodiments. The components of system 300 may correspond to components of the multi-candidate SCL decoder 260 and/or the physical layer components 250 of FIG. 2. For example, the system 300 includes physical layer components 304, which may correspond to physical layer components 250 of the receive chain in FIG. 2. The system 300 may further include packaging circuitry 308, polar decoders 312a-b, and CRC check components 316a-b, which may be included in the multi-candidate successive cancellation list decoder 260 of FIG. 2. The system 300 of FIG. 3 is described with reference to blind decoding of DCI. It will be understood that the system 300 may additionally or alternatively be used to decode another type of signal, such as PBCH.

In an example, the physical layer components 304 may perform PDCCH processing and demodulation on received resources and output candidate codewords. The candidate codewords may include soft bits (e.g., LLR values corresponding to a LLR vector) and/or hard bits.

The packaging circuitry 308 may group the candidate codewords into respective packages for processing by respective decoders 312a-b. Individual packages may include one or more candidate codewords. For example, the packaging circuitry 308 may receive N candidate codewords (e.g., up to 44 codewords for 5G NR FR1) and allocate the candidate codewords to M packages. The packages may or may not include the same number of candidate codewords, e.g., based on the characteristics and/or number of the candidate codewords.

In an example, the packaging circuitry 308 may group the candidate codewords into the packages so that at most one candidate codeword in an individual package may be valid (e.g., include DCI intended for the UE). Such packaging may be referred to as contradictory packaging. As further discussed below, the decoder 312a-b and corresponding CRC check component 316a-b can process the multiple candidate codewords and output a single codeword (e.g., the valid codeword) that passes the CRC check. Note that it is possible (and may frequently occur) that none of the candidate codewords in an individual package are valid.

For example, a package of contradictory candidate codewords may include two or more candidate codewords with the same input (e.g., LLR input and/or hard bit input) and different code configurations (e.g., DCI formats). The DCI formats may have different DCI lengths and/or frozen bit mapping. In an example, the two or more candidate codewords may be considered to have the same LLR input based on their LLR inputs having a same starting resource (e.g., control channel element (CCE)), same aggregation level, and/or same/similar scrambling. One example of contradictory DCI formats that may be associated with the same LLR input (e.g., starting CCE) is DCI format 0_1 for uplink unicast grant and DCI format 1_1 for downlink unicast grant for a UE in connected mode where the UE monitors for the DCI in a UE-specific search space.

In another example, a package of contradictory candidate codewords may include two or more candidate codewords with different inputs and partially overlapping resources (e.g., CCEs and/or resource element groups (REGs)). The candidate codewords with different inputs may have the same code configuration (e.g., DCI format). For example, the search space may include multiple candidates at various aggregation levels such that they have overlapping CCEs/REGs.

Accordingly, the multi-candidate SCL decoder may be used to monitor for multiple DCI formats in a same set of resources. Additionally, the multi-candidate SCL decoder may be used to monitor for the same DCI format in different sets of resources (e.g., which are overlapping). In some embodiments, these packaging techniques may be combined, e.g., to generate a package of candidate codewords that includes candidate codewords with different LLR inputs and with different DCI formats. For example, a package may include a×b candidate codewords, where a is the number of different LLR inputs and b is the number of different DCI formats for which each LLR input is checked.

Although not required, the multi-candidate SCL decoder may work more efficiently if the contradictory candidates have the same mother code length (even if they have different rate-matched code lengths). Accordingly, the package circuitry 308 may group the candidate codewords into packages based further on the mother code length of the candidate codewords. In an example, the mother code length may be 128, 256, or 512.

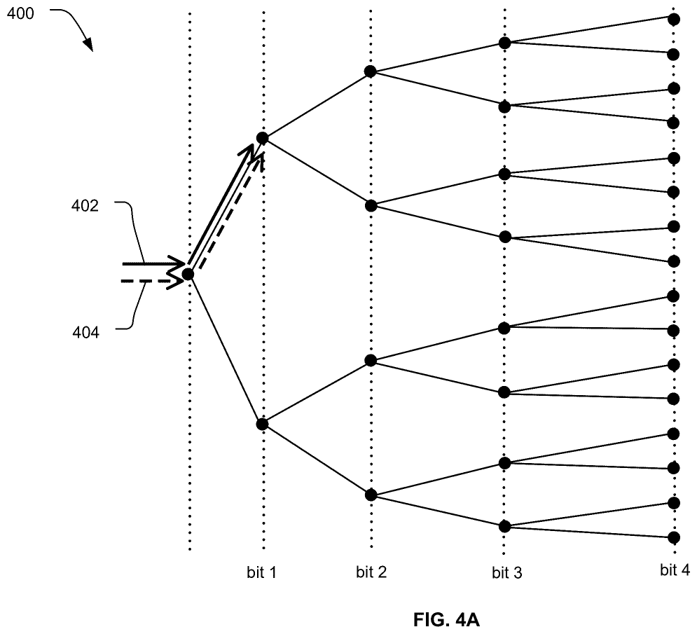

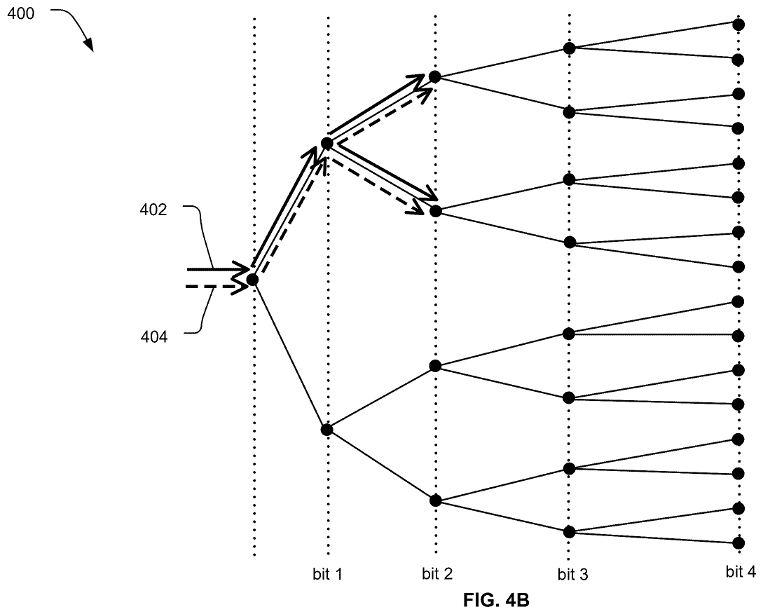

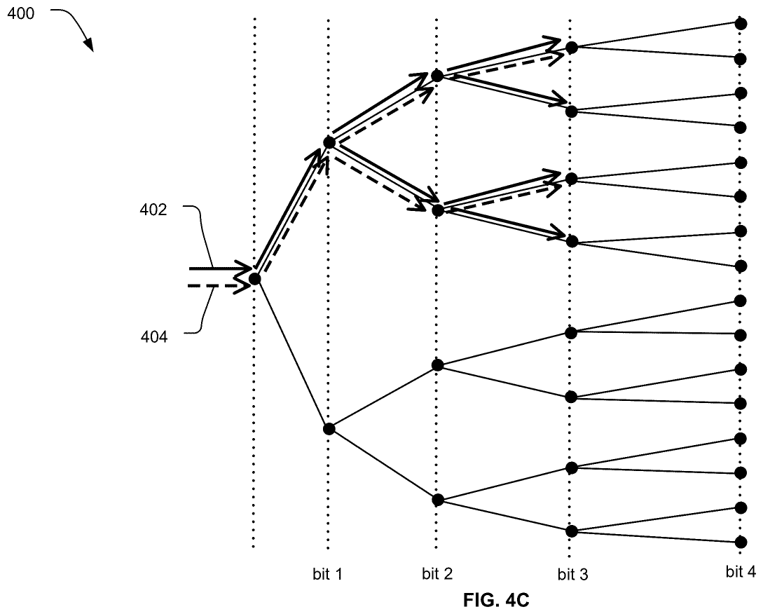

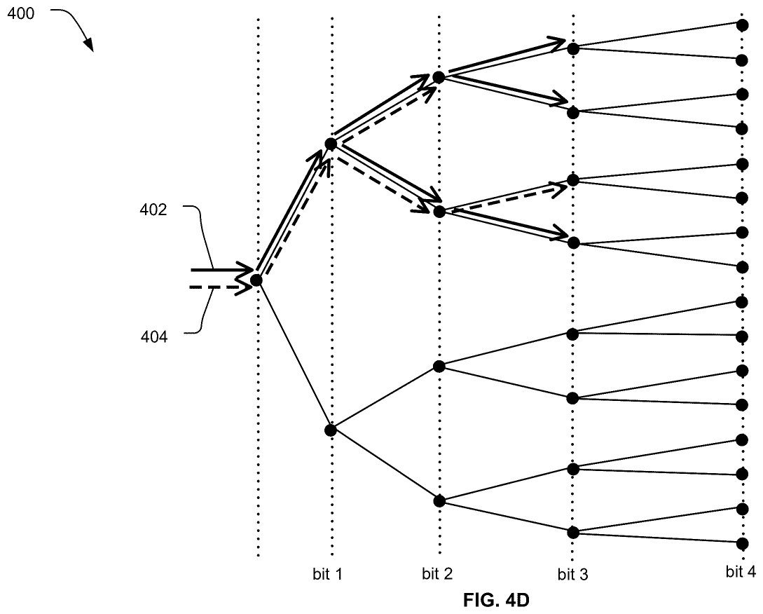

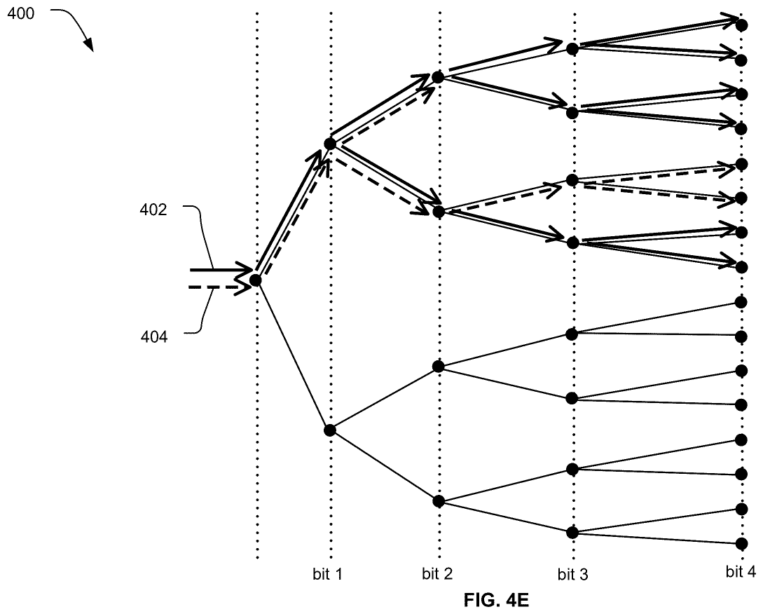

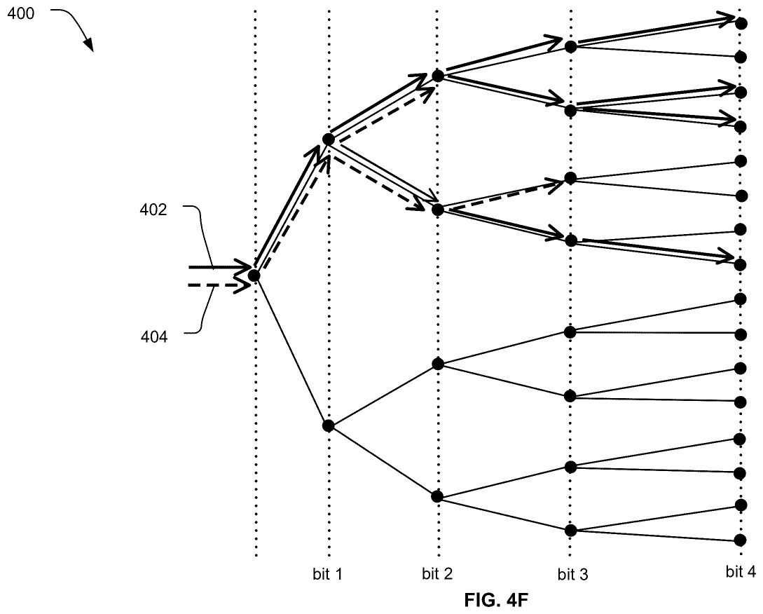

The decoders 312a-b may receive the package of candidate codewords and perform decoding on them simultaneously using SCL decoding (e.g., as further described with respect to FIGS. 4A-4F and elsewhere herein). The output of the decoder 312a-b may include multiple paths with respective path metrics. The CRC check component 316a-b may perform a CRC check on the respective paths. The path with the best path metric that also passes CRC (if any) may be output as the output of the multi-candidate SCL decoder.

In an example, the CRC encoding may be scrambled with a radio network temporary identifier (RNTI) associated with the UE. Accordingly, the CRC check may be based on the RNTI.

In embodiments, the multi-candidate SCL decoder may use an enhanced path metric, which may be referred to as a blind detection path metric (BDPM). Since the difference in DCI formats affects the code rate and hence the valid codeword space, the BDPM may be based on analysis of the valid codeword space. As an example, Aₖ may denote the set of valid sequences with k-bit DCI, which includes all the possible transmitted sequences

$${v}_{1}^{n}$$

when the DCI length is k. Since the frozen bits are set to logic 0, the size of Aₖ may be given by Aₖ=2^{k}. Considering the differences of the valid codeword spaces, the BDPM may incorporate the probability of the event that both the decoding results and the assumption of DCI lengths are correct. In an example, the BDPM upon decoding the j^{th} bit is defined as:

$$P ( {\hat{v}}_{1}^{j} , {A}_{k} \vert {y}_{1}^{n} ) = \frac{P ( {\hat{v}}_{1}^{j} = {v}_{1}^{j} , {y}_{1}^{n} ) P ( {v}_{1}^{j} is a codeword preset in {A}_{k} )}{P ( {y}_{1}^{n} )} = P ( {\hat{v}}_{1}^{j} = {v}_{1}^{j} \vert {y}_{1}^{n} ) P ( {v}_{1}^{j} is a codeword preset in {A}_{k} )$$

where

$$P ( {\hat{v}}_{1}^{j} = {v}_{1}^{j} \vert {y}_{1}^{n} )$$

denotes the probability of correct decoding up to bit j; and P(

$${v}_{1}^{j}$$

is a codeword preset in Aₖ) denotes the probability of the event that

$${v}_{1}^{j}$$

is a preset to a transmitted sequence such as

$${v}_{1}^{N} ,$$

when the length of the transmitted DCI is k. Since the information bits are uniformly distributed in {0, 1}, the probability that sequence

$${v}_{1}^{n}$$

is included in

$${A}_{k} ( P ( {v}_{1}^{n} ∈ {A}_{k} )$$

may be calculated as

$${2}^{- k} .$$

Assuming there are k′ information bits (non-frozen bits) decoded until the j^{th} bit, there are 2^{k-k′} many ways to expand the decoding path and generate

$${v}_{1}^{n}$$

codewords. Accordingly,

$$P ( {v}_{1}^{j}$$

is a codeword preset in

$${A}_{k} ) = \frac{1}{{2}^{k - {k}^{′}}} .$$

Combining with the path metric described above based on the computed soft bits so far, the BDPM may be defined as:

$$- {\sum }_{i = 1}^{j} log [ 1 + exp [ 2 {\hat{v}}_{i} - 1 ) α ( {\hat{v}}_{i} ) ] ] - \vert {ℱ}^{c} ⋂ \{ 1 , 2 , … , j \} \vert \times log2 ,$$

where [symbol] is the subset of frozen indices, and [symbol] ^{c} is its complement subset. In other words, | [symbol] ^{c}∩{1, 2, . . . , j}| denotes the number of non-frozen bits in {1, 2, . . . , j}.

Accordingly, the BDPM enhances the path metric based on properties of the DCI formats to enhance the discrimination between valid DCIs compared with random modulated symbol vectors. The difference between the DCI formats may be captured in their corresponding frozen bit mappings, which determine the extension rules for individual candidates during the multi-candidate SCL decoding. The BDPM may assign an additional metric penalty when the candidate is decoded over a non-frozen bit as these bits are typically less noisy if the correct DCI format is chosen.

An example operation of the multi-candidate SCL decoder will be described with reference to FIGS. 4A-4F. FIGS. 4A-4F illustrates a binary decision tree 400 to process a first candidate codeword 402 and a second candidate codeword 404. The operation of the multi-candidate SCL decoder is described with reference to the first candidate codeword 402 and the second candidate codeword 404 having the same LLR input and different DCI formats. However, a similar procedure may be used for candidate codewords that have different LLR inputs.

In the example of FIGS. 4A-4F, the first candidate codeword 402 has a first DCI format and the second candidate codeword 404 has a second DCI format. The first and second DCI formats have different frozen bit mappings. The frozen bit mapping corresponds to bit positions in the codeword that have a predefined value (e.g., logic 0) based on the encoding process. The bit positions in the codeword other than the frozen bits correspond to information bits.

For a bit position in the binary decision tree 400 for which the respective candidate codeword has a frozen bit, the path may be extended only in the direction of the frozen bit value. For a bit position in the binary decision tree 400 for which the respective candidate codeword has a non-frozen bit (e.g., information bit), the path may be extended in both directions (e.g., assuming the bit position has a logic 0 and assuming the bit position has a logic 1). When the number of paths exceeds the list size (e.g., 4 in the example of FIG. 4), a subset (corresponding to the list size) of the paths with the best path metrics (e.g., BDPM) may be kept and the additional paths (with the worst path metrics) may be discarded (referred to as pruning). The path extensions for the different candidate codewords (e.g., with different frozen bit mappings or the same frozen bit mapping) may be performed in parallel to enable simultaneous decoding of the candidate codewords.

In an example, at the first bit position (bit 1), both the first candidate codeword 402 and the second candidate codeword 404 have a frozen bit. Accordingly, as shown in FIG. 4A, the paths are extended based on the first bit being logic 0.

At the second bit position (bit 2), both the first candidate codeword 402 and the second candidate codeword 404 have a non-frozen (information) bit. Accordingly, as shown in FIG. 4B, the paths are extended in both directions (e.g., based on the second bit being logic 0 and based on the second bit being logic 1). The total number of paths is 4, which is equal to the list size so no pruning is needed.

At the third bit position (bit 3), the first candidate codeword 402 has a non-frozen bit and the second candidate codeword 404 has a frozen bit. Accordingly, as shown in FIG. 4C, the two branches of the first candidate codeword 402 are each extended in both directions, while the two branches of the second candidate codeword 404 are each extended in one direction (based on the frozen bit). As shown in FIG. 4D, the 6 paths are pruned to 4 paths based on the respective path metrics. For example, the 4 paths with the greatest path metric are kept and the 2 paths with the lowest path metric are pruned.

At the fourth bit position (bit 4), both the first candidate codeword 402 and the second candidate codeword 404 have a non-frozen bit. Accordingly, as shown in FIG. 4E, each surviving path is extended in both directions, resulting in 8 total paths. As shown in FIG. 4F, pruning the 8 paths to 4 paths results in discarding the remaining paths that correspond to the second candidate codeword 404. Accordingly, only paths that correspond to the first candidate codeword 402 remain.

In embodiments, the multi-candidate SCL decoder may perform CRC check on the remaining paths (e.g., based on a RNTI associated with the UE and/or the search space configurations for the candidate codewords). The paths with the best (e.g., highest) path metric that passes the CRC check (if any) may be selected as the output of the multi-candidate SCL decoder.

Accordingly, the multi-candidate SCL decoder may enable simultaneous decoding of multiple candidate codewords (e.g., with different DCI formats). As illustrated in the example of FIGS. 4A-4F, an invalid codeword may be eliminated from consideration prior to completion of the decoding process. In such instances, the remaining candidate codeword still has a number of paths equal to the list size.

The multi-candidate SCL decoder may be extended to process more than two DCI formats simultaneously. Additionally, or alternatively, the multi-candidate SCL decoder may be used to decode candidates that have different LLR vectors (e.g., that come from different CCEs). In an example, the LLR inputs to the decoder may have the same length. The decoder can input them in a single binary decision tree and process them jointly. The natural detection capability of the BDPM may enable the decoder to naturally eliminate an invalid PDCCH candidate during the decoding process. Accordingly, the multi-candidate SCL decoder may save computational power compared with using separate decoders.

In the case of imperfect channel estimates, the LLR values of different candidates may vary in one or more quality metrics (e.g., SNR). In an example, the LLR values of different candidates in a package may be scaled to compensate for (e.g., equalize) the one or more quality metrics.

In another example, pure noise vectors may be pruned from the LLR input prior to the decoding process.

The multi-candidate SCL decoding architecture may include additional memory to store tags for the respective PDCCH candidates to track them through the decoding process. The tag may be, for example, a single bit to distinguish between two PDCCH candidates or two bits to distinguish between four PDCCH candidates. Additional memory may also be required at the initiation stage to store the multiple candidates that are input to the multi-candidate SCL decoder, however this is equivalent to the total memory that would be required if the candidates were decoded individually by separate decoders.

In an example, the multi-candidate SCL decoder may replace a multi-threaded SCL decoder. In another example, the multi-candidate SCL decoder may be multi-threaded itself. The multi-threaded, multi-candidate SCL decoder may decode multiple batches of PDCCH candidates simultaneously via respective SCL hardware.

As discussed above, in an example, the packaging circuitry may allocate PDCCH candidates to respective packages such that individual packages include PDCCH candidates with a same mother code length. The mother code length may be determined after removing the rate-matching effect, which is typically a power of 2, such as 128, 256, or 512.

In another example, the multi-candidate SCL decoder may be configured to simultaneously decode candidates with different mother code lengths. For example, the multi-candidate SCL decoder may include a hard decision module on internal decoding nodes (e.g., above the leaves). Additionally, or alternatively, the BDPM may be modified to capture the different in mother code lengths.

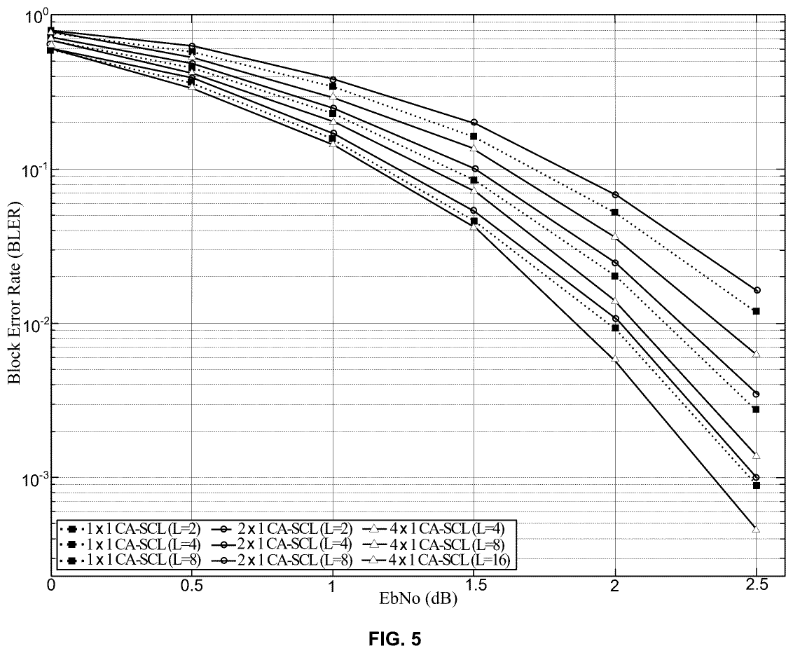

FIG. 5 illustrates a block error rate (BLER) comparison for a 1×1 (conventional), 2×1 (dual input, single DCI), and 4×1 (quad input single DCI) multi-candidate CA-SCL decoding scheme at various list sizes (L=2, 4, 8, 16). The 1×1 decoder can also be interpreted as a genie-aided decoder, where the decoder is aware of the candidate with valid DCI. At an SNR of EbN0=2.0-2.5 dB, the SC decoder (no list) has a BLER of around 10-20% and a CA-SCL with L=8 has a BLER of about 10-3. As shown, at this SNR region, a single decoder circuit is able to process and decode up to four candidates simultaneously without significant performance reduction (and without consuming additional time/power). With a fixed list size (e.g., comparing the same list size for single input and multiple inputs), the performance gap at this SNR region may be less than 0.1 dB. The performance may be improved with a larger list size. For example, using a list size of L=16 and processing four PDCCH candidates simultaneously improves performance and yields a 50% power reduction compared with using separate decoders.

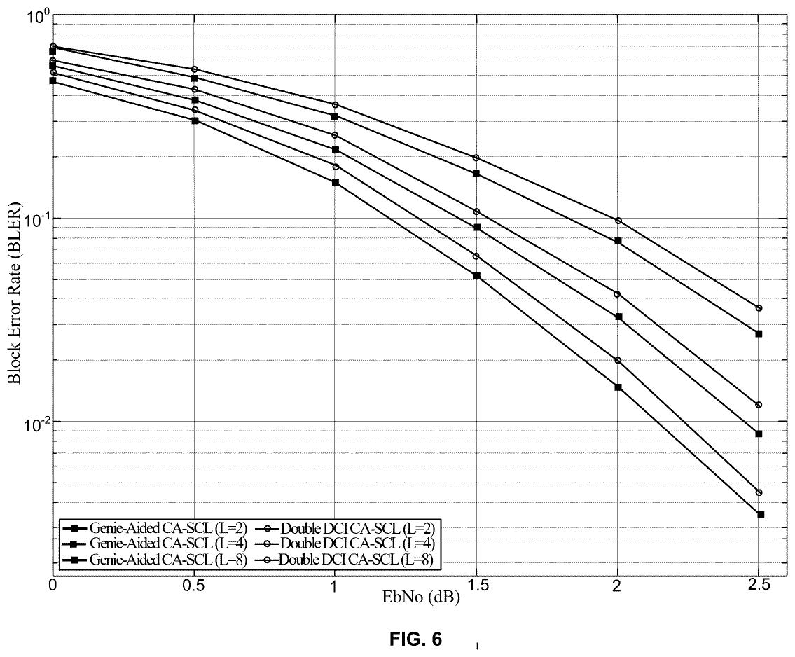

FIG. 6 illustrates a performance comparison (BLER) between a 1×1 (genie-aided) CA-SCL decoder and 1×2 (single input, dual DCI) CA-SCL decoder at various list sizes (L=2, 4, 8). In the example, there are two possible DCI formats with DCI lengths given by A₁=64 and A₂=68, respectively. In the simulation of FIG. 6, the valid DCI for transmission over PDCCH is chosen at random. The genie-aided decoder is aware of the candidate with valid DCI. Accordingly, the BLER of the genie-aided decoder is equivalent to that of the conventional SCL decoder where all candidates are decoded individually (excluding CRC false-positive errors). As shown in FIG. 6, the 1×2 decoder can concurrently decode both DCI formats while maintaining similar performance (e.g., less than 0.1 dB SNR loss). The performance gap becomes smaller at larger list size.

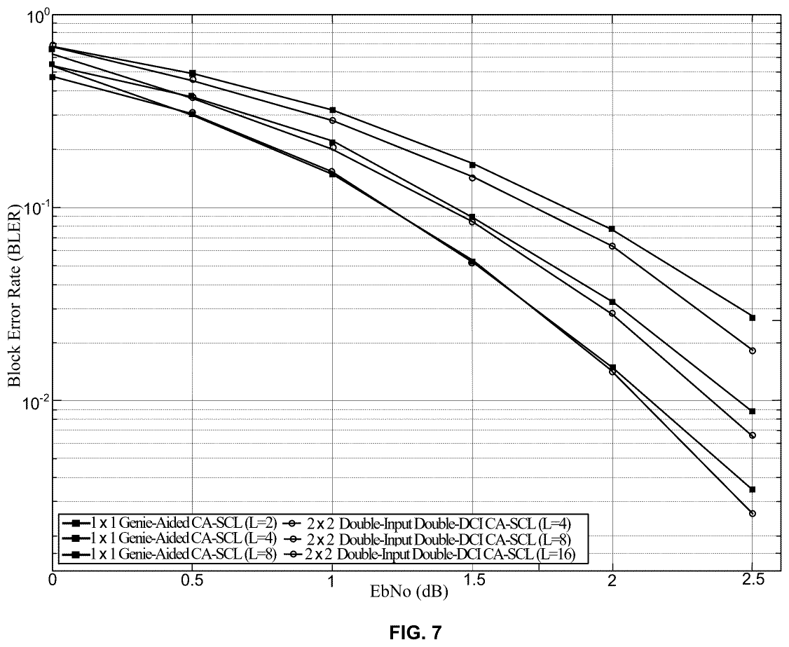

FIG. 7 illustrates a performance comparison (BLER) between a 1×1 (genie-aided) CA-SCL decoder and a 2×2 (dual input, dual DCI) CA-SCL decoder at various list sizes (L=2, 4, 8, 16). In the example, there are two possible DCI formats with DCI lengths given by A₁=64 and A₂=68, respectively. The valid DCI is chosen at random and mapped to one of the PDCCH candidates at random, while the other PDCCH candidate includes random symbols (e.g., quadrature phase-shift keying (QPSK) symbols). The genie-aided decoder is aware of the candidate with valid DCI and its DCI format. Accordingly, the BLER of the genic-aided decoder is equivalent to that of the conventional SCL decoder where all candidates are decoded individually (excluding CRC false-positive errors). As shown in FIG. 7, the 2×2 decoder can concurrently decode all four PDCCH candidates without a significant loss in performance. In fact, a 2×2 decoder at double the list size (2×L) outperforms the conventional decoder while consuming half the power in total.

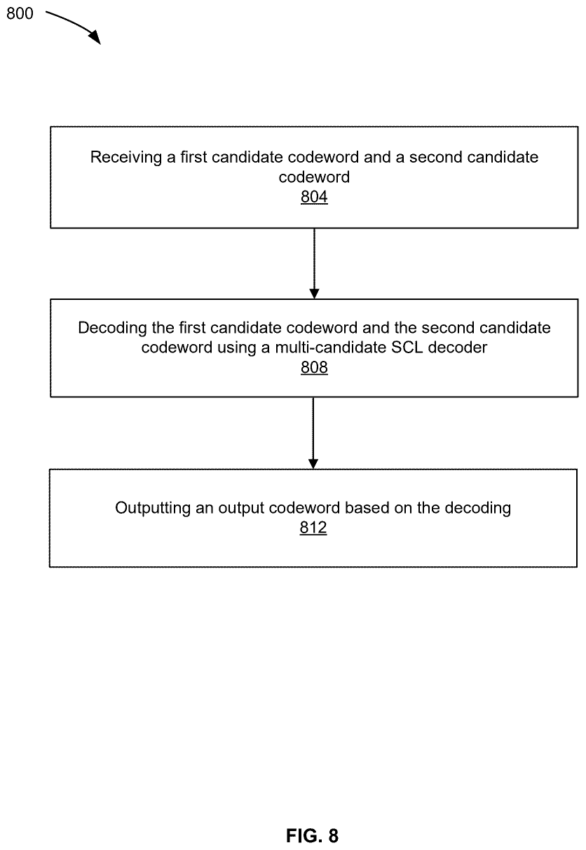

FIG. 8 illustrates an example of an operational flow/algorithmic structure 800 for multi-candidate SCL decoding in accordance with some embodiments. The operational flow/algorithmic structure 800 can be implemented by a UE (e.g., performed by components thereof including, for example, an apparatus of the UE, where the apparatus includes processing circuitry; a modem is an example of such an apparatus). The UE can be any of the UEs described herein. In some embodiments, the operational flow/algorithmic structure 800 may be implemented by executing instructions stored in a tangible, non-transitory, computer-readable storage medium, such as a memory of the UE. In another example, the operational flow/algorithmic structure 1000 can be implemented by a base station (e.g., a gNB, such as performed by components thereof including, for example, an apparatus of the base station, where the apparatus includes processing circuitry). While the operational flow/algorithmic structure 800 is described using steps in a specific sequence, it should be understood that the present disclosure contemplates that the described steps may be performed in different sequences than the sequence illustrated, and certain described steps may be omitted or not performed altogether.

In an example, the operational flow/algorithmic structure 800 includes, at 804, receiving a first candidate codeword and a second candidate codeword. The first and second candidate codewords may correspond to PDCCH candidates, PBCH candidates, or other decoding candidates. In some embodiments, the first and second candidates may be allocated to a package of decoding candidates so that at most one of the candidates in the package is valid (e.g., is intended for the UE). In one example, the first and second candidate codewords may have a same input (e.g., soft bit input, such as LLR input, and/or hard bit input) and different code configurations (e.g., DCI formats). In another example, the first and second candidate codewords may have a same code configuration and different inputs. In an example, the first and second candidate codewords may be allocated to the package based on having a same mother code length. The mother code length may be determined after removing the rate-matching effect. In some embodiments, the package may include more than two candidate codewords, e.g., as described with respect to a 2×2 decoder and/or a 1×4 decoder.

In an example, the operational flow/algorithmic structure 800 further includes, at 808, decoding the first candidate codeword and the second candidate codeword using a multi-candidate SCL decoder. The multi-candidate SCL decoder may perform SCL decoding on the first and second candidate codewords contemporaneously (e.g., via a same binary decoding tree). In an example, the decoding may include pruning one or more paths based on a BDPM. The BDPM may be based on a likelihood that the respective paths are included in a set of valid bit sequences (e.g., Aₖ). In some embodiments, the BDPM may be further based on an input normalization and/or a difference in code configurations of the candidate codewords.

In an example, the operational flow/algorithmic structure 800 further includes, at 812, outputting an output codeword based on the decoding. The output codeword may correspond to one of the first or second candidate codewords (e.g., the first candidate codeword). In an example, the decoding generates multiple candidate paths and a CRC check may be performed on the candidate paths. The output codeword may correspond to the candidate path with the best (e.g., highest) BDPM that passes the CRC check.

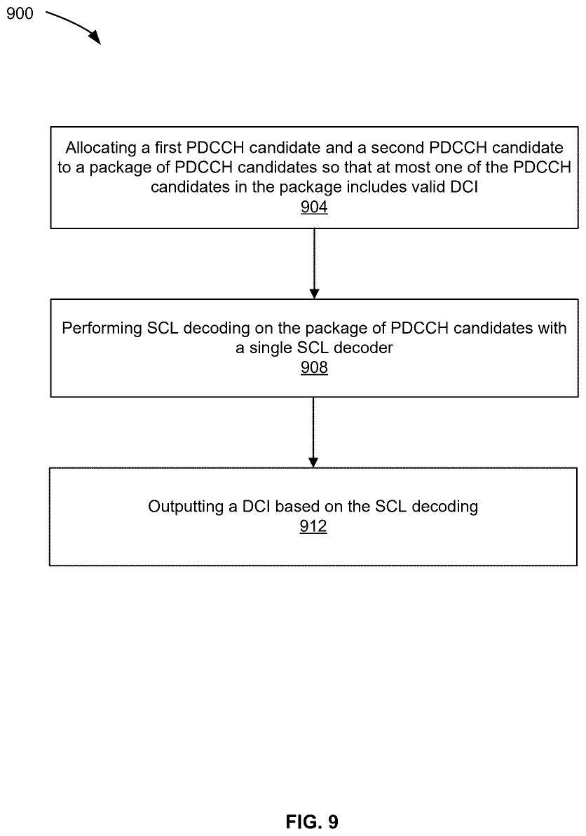

FIG. 9 illustrates another example of an operational flow/algorithmic structure for multi-candidate SCL decoding in accordance with some embodiments. The operational flow/algorithmic structure 900 can be implemented by a UE (e.g., performed by components thereof including, for example, an apparatus of the UE, where the apparatus includes processing circuitry; a modem is an example of such an apparatus). The UE can be any of the UEs described herein. In some embodiments, the operational flow/algorithmic structure 900 may be implemented by executing instructions stored in a tangible, non-transitory, computer-readable storage medium, such as a memory of the UE. While the operational flow/algorithmic structure 900 is described using steps in a specific sequence, it should be understood that the present disclosure contemplates that the described steps may be performed in different sequences than the sequence illustrated, and certain described steps may be omitted or not performed altogether. Further, one or more operations of the operational flow/algorithmic structure 900 can include one or more operations of the operational flow/algorithmic structure 800.

In an example, the operational flow/algorithmic structure 900 includes, at 904, allocating a first PDCCH candidate and a second PDCCH candidate to a package of PDCCH candidates so that at most one of the PDCCH candidates in the package includes valid DCI. In one example, the first and second PDCCH candidates may have a same input (e.g., LLR input) and different DCI formats. In another example, the first and second PDCCH candidates may have a same DCI format and different inputs. In an example, the allocating may be performed based further on a mother code length of the candidate codewords, e.g., the first and second candidate codewords may have a same mother code length. The mother code length may be determined after removing the rate-matching effect. In some embodiments, the package may include more than two PDCCH candidates, e.g., as described with respect to a 2×2 decoder and/or a 1×4 decoder.

In an example, the operational flow/algorithmic structure 900 further includes, at 908, performing multi-candidate SCL decoding on the package of PDCCH candidates with a single SCL decoder. The single SCL decoder may correspond to the multi-candidate SCL decoder described herein. The multi-candidate SCL decoder may perform SCL decoding on the first and second candidate codewords contemporaneously via a binary decoding tree. In an example, the decoding may include pruning one or more paths based on a BDPM. The BDPM may be based on a likelihood that the respective paths are included in a set of valid bit sequences (e.g., Aₖ).

In an example, the operational flow/algorithmic structure 900 further includes, at 912, outputting a DCI based on the multi-candidate SCL decoding. The DCI corresponds to one of the first or second PDCCH candidates (e.g., the first PDCCH candidate). In an example, the output DCI may correspond to the path with the highest BDPM that also passes the CRC check.

Although the operational flow/algorithmic structure 900 is described with respect to decoding PDCCH candidates, a similar operational flow/algorithmic structure 900 may be used to decode other types of decoding candidates, such as PBCH candidates, in accordance with embodiments herein.

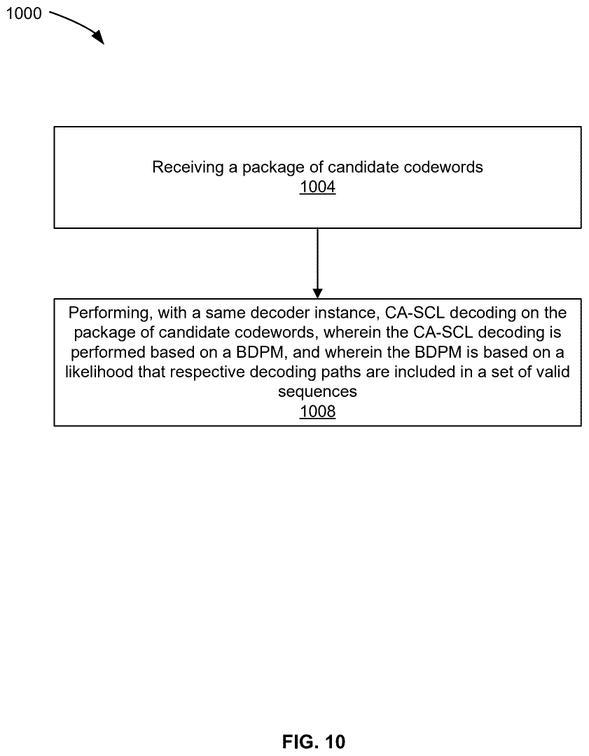

FIG. 10 illustrates another example of an operational flow/algorithmic structure for multi-candidate SCL decoding in accordance with some embodiments. The operational flow/algorithmic structure 1000 can be implemented by a UE (e.g., performed by components thereof including, for example, an apparatus of the UE, where the apparatus includes processing circuitry; a modem is an example of such an apparatus). The UE can be any of the UEs described herein. In some embodiments, the operational flow/algorithmic structure 1000 may be implemented by executing instructions stored in a tangible, non-transitory, computer-readable storage medium, such as a memory of the UE. In another example, the operational flow/algorithmic structure 1000 can be implemented by a base station (e.g., a gNB, such as performed by components thereof including, for example, an apparatus of the base station, where the apparatus includes processing circuitry). While the operational flow/algorithmic structure 1000 is described using steps in a specific sequence, it should be understood that the present disclosure contemplates that the described steps may be performed in different sequences than the sequence illustrated, and certain described steps may be omitted or not performed altogether. Further, one or more operations of the operational flow/algorithmic structure 1000 can include one or more operations of the operational flow/algorithmic structure 800 and/or 900.

In an example, the operational flow/algorithmic structure 1000 includes, at 1004, receiving a package of candidate codewords. In an example, candidate codewords may be allocated to the package so that at most one of the candidates in the package is valid (e.g., is intended for the UE). In one example, the package may include candidate codewords with a same input (e.g., LLR input and/or hard bit input) and different code configurations (e.g., DCI formats for PDCCH candidates) and/or a same code configuration and different inputs. For example, the candidate codewords may correspond to PDCCH candidates, PBCH candidates, and/or other decoding candidates. The package may include any suitable number of two or more candidate codewords. In some instances, the package may not include any valid candidates.

In an example, the operational flow/algorithmic structure 1000 further includes, at 1008, performing, with a same decoder instance, multi-candidate CA-SCL decoding on the package of candidate codewords contemporaneously, wherein the multi-candidate CA-SCL decoding is performed based on a BDPM, and wherein the BDPM is based on a likelihood that respective decoding paths are included in a set of valid sequences. The decoder instance may correspond to the multi-candidate SCL decoder described herein. The multi-candidate SCL decoder may perform SCL decoding on the package of candidate codewords contemporaneously via a binary decoding tree. In an example, the decoding may include pruning one or more paths based on the BDPM. If the package includes a valid sequence (e.g., valid DCI), the decoder may output a codeword that corresponds to the valid sequence. The valid sequence may correspond to the path with the best BDPM that also passes the CRC check.

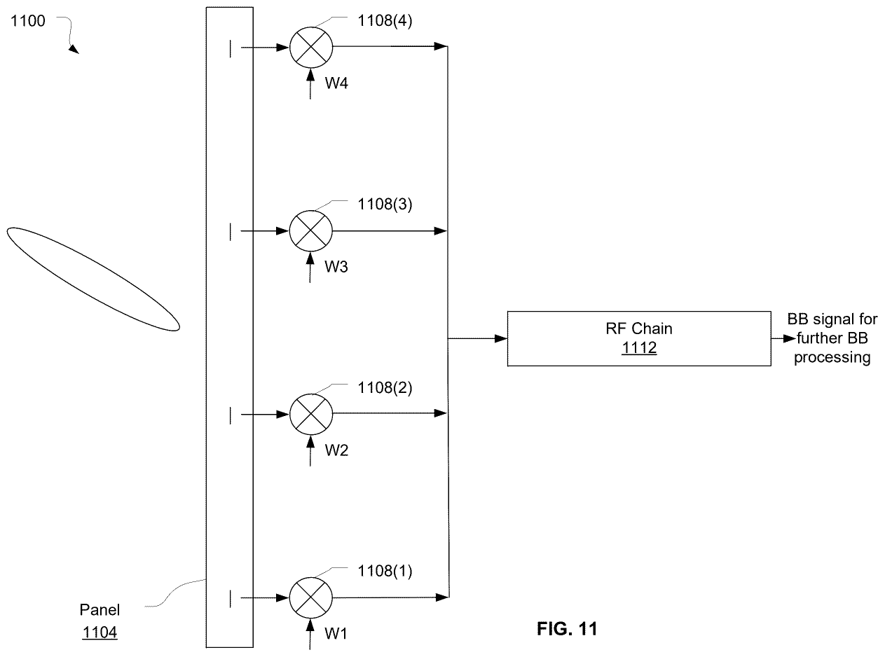

FIG. 11 illustrates receive components 1100 of a UE, such as any of the UE's described herein above, in accordance with some embodiments. The receive components 1100 may include an antenna panel 1104 that includes a number of antenna elements. The panel 1104 is shown with four antenna elements, but other embodiments may include other numbers.

The antenna panel 1104 may be coupled to analog beamforming (BF) components that include a number of phase shifters 1108(1)-1108(4). The phase shifters 1108(1)-1108(4) may be coupled with a radio-frequency (RF) chain 1112. The RF chain 1112 may amplify a receive analog RF signal, downconvert the RF signal to baseband, and convert the analog baseband signal to a digital baseband signal that may be provided to a baseband processor for further processing. In an example, receive components 1100 can include multiple antenna panels 1104 and/or multiple RF chains 1112. An MR can include an antenna panel 1104 and an RF chain 1112. An LP-WUR can include the same antenna panel 1104 or a different antenna panel and a different RF chain 1112.

In various embodiments, control circuitry, which may reside in a baseband processor, may provide BF weights (for example W1-W4), which may represent phase shift values, to the phase shifters 1108(1)-1108(4) to provide a receive beam at the antenna panel 1104. These BF weights may be determined based on the channel-based beamforming.

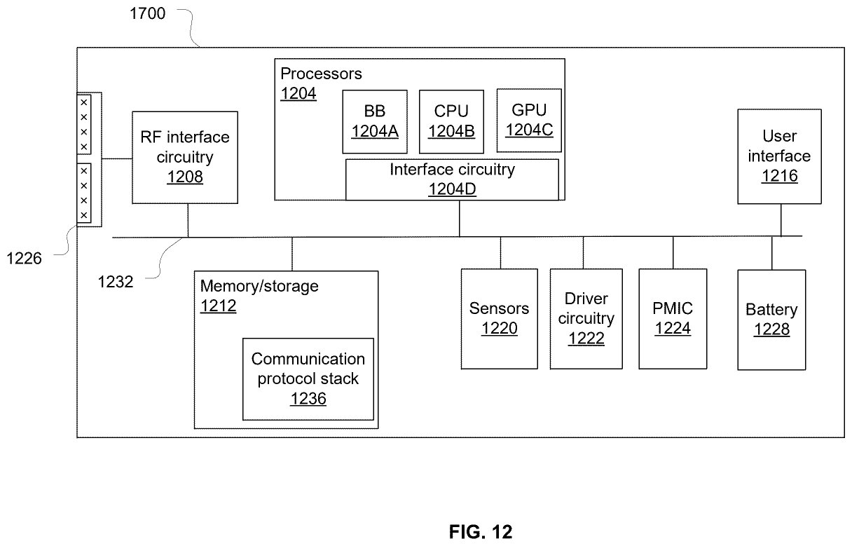

FIG. 12 illustrates a UE 1200, in accordance with some embodiments. The UE 1200 may be similar to and substantially interchangeable with any of the UEs described herein above. Particularly, the UE 1200 can support multi-candidate SCL decoding of polar codes at its receive chain. The UE 1200 may also support polar codes encoding at its transmit chain.

Similar to that described above with respect to UE 104, the UE 1200 may be any mobile or non-mobile computing device, such as mobile phones, computers, tablets, industrial wireless sensors (for example, microphones, carbon dioxide sensors, pressure sensors, humidity sensors, thermometers, motion sensors, accelerometers, laser scanners, fluid level sensors, inventory sensors, electric voltage/current meters, actuators, etc.), video surveillance/monitoring devices (for example, cameras, video cameras, etc.), wearable devices, or relaxed-IoT devices. In some embodiments, the UE may be a reduced capacity UE or NR-Light UE.

The UE 1200 may include processors 1204, RF interface circuitry 1208, memory/storage 1212, user interface 1216, sensors 1220, driver circuitry 1222, power management integrated circuit (PMIC) 1224, and battery 1228. The components of the UE 1200 may be implemented as integrated circuits (ICs), portions thereof, discrete electronic devices, or other modules, logic, hardware, software, firmware, or a combination thereof. The block diagram of FIG. 12 is intended to show a high-level view of some of the components of the UE 1200. However, some of the components shown may be omitted, additional components may be present, and different arrangements of the components shown may occur in other implementations.

The components of the UE 1200 may be coupled with various other components over one or more interconnects 1232, which may represent any type of interface, input/output, bus (local, system, or expansion), transmission line, trace, optical connection, etc. that allows various circuit components (on common or different chips or chipsets) to interact with one another.

The processors 1204 may include processor circuitry, such as baseband processor circuitry (BB) 1204A, central processor unit circuitry (CPU) 1204B, and graphics processor unit circuitry (GPU) 1204C. The processors 1204 may include any type of circuitry or processor circuitry that executes or otherwise operates computer-executable instructions, such as program code, software modules, or functional processes from memory/storage 1212 to cause the UE 1200 to perform operations as described herein.

In some embodiments, the baseband processor circuitry 1204A may access a communication protocol stack 1236 in the memory/storage 1212 to communicate over a 3GPP compatible network. In general, the baseband processor circuitry 1204A may access the communication protocol stack to: perform user plane functions at a PHY layer, MAC layer, RLC layer, PDCP layer, SDAP layer, and PDU layer; and perform control plane functions at a PHY layer, MAC layer, RLC layer, PDCP layer, RRC layer, and a non-access stratum “NAS” layer. In some embodiments, the PHY layer operations may additionally/alternatively be performed by the components of the RF interface circuitry 1208.

The baseband processor circuitry 1204A may generate or process baseband signals or waveforms that carry information in 3GPP-compatible networks. In some embodiments, the waveforms for NR may be based on cyclic prefix OFDM (CP-OFDM) in the uplink or downlink, and discrete Fourier transform spread OFDM (DFT-S-OFDM) in the uplink.

The baseband processor circuitry 1204A may also access group information from memory/storage 1212 to determine search space groups in which a number of repetitions of a PDCCH may be transmitted.

The memory/storage 1212 may include any type of volatile or non-volatile memory that may be distributed throughout the UE 1200. In some embodiments, some of the memory/storage 1212 may be located on the processors 1204 themselves (for example, L1 and L2 cache), while other memory/storage 1212 is external to the processors 1204 but accessible thereto via a memory interface. The memory/storage 1212 may include any suitable volatile or non-volatile memory, such as, but not limited to, dynamic random-access memory (DRAM), static random-access memory (SRAM), erasable programmable read-only memory (EPROM), electrically erasable programmable read-only memory (EEPROM), Flash memory, solid-state memory, or any other type of memory device technology.

The RF interface circuitry 1208 may include transceiver circuitry and a radio frequency front end module (RF FEM) that allows the UE 1200 to communicate with other devices over a radio access network. The RF interface circuitry 1208 may include various elements arranged in transmit or receive paths. These elements may include, for example, switches, mixers, amplifiers, filters, synthesizer circuitry, control circuitry, etc.

In the receive path, the RF FEM may receive a radiated signal from an air interface via an antenna 1250 and proceed to filter and amplify (with a low-noise amplifier) the signal. The signal may be provided to a receiver of the transceiver that down-converts the RF signal into a baseband signal that is provided to the baseband processor of the processors 1204.

In the transmit path, the transmitter of the transceiver up-converts the baseband signal received from the baseband processor and provides the RF signal to the RF FEM. The RFEM may amplify the RF signal through a power amplifier prior to the signal being radiated across the air interface via the antenna 1250.

In various embodiments, the RF interface circuitry 1208 may be configured to transmit/receive signals in a manner compatible with NR access technologies.

The antenna 1250 may include a number of antenna elements that each convert electrical signals into radio waves to travel through the air and to convert received radio waves into electrical signals. The antenna elements may be arranged into one or more antenna panels. The antenna 1250 may have antenna panels that are omnidirectional, directional, or a combination thereof to enable beamforming and multiple input, multiple output communications. The antenna 1250 may include microstrip antennas, printed antennas fabricated on the surface of one or more printed circuit boards, patch antennas, phased array antennas, etc. The antenna 1250 may have one or more panels designed for specific frequency bands including bands in FR1 or FR2.

The user interface circuitry 1216 includes various input/output (I/O) devices designed to enable user interaction with the UE 1200. The user interface 1216 includes input device circuitry and output device circuitry. Input device circuitry includes any physical or virtual means for accepting an input including, inter alia, one or more physical or virtual buttons (for example, a reset button), a physical keyboard, keypad, mouse, touchpad, touchscreen, microphones, scanner, headset, or the like. The output device circuitry includes any physical or virtual means for showing information or otherwise conveying information, such as sensor readings, actuator position(s), or other like information. Output device circuitry may include any number or combinations of audio or visual display, including, inter alia, one or more simple visual outputs/indicators (for example, binary status indicators, such as light emitting diodes (LEDs) and multi-character visual outputs, or more complex outputs, such as display devices or touchscreens (for example, liquid crystal displays (LCDs), LED displays, quantum dot displays, projectors, etc.), with the output of characters, graphics, multimedia objects, and the like being generated or produced from the operation of the UE 1200.

The sensors 1220 may include devices, modules, or subsystems whose purpose is to detect events or changes in its environment and send the information (sensor data) about the detected events to some other device, module, subsystem, etc. Examples of such sensors include, inter alia, inertia measurement units comprising accelerometers; gyroscopes; or magnetometers; microelectromechanical systems or nanoelectromechanical systems comprising 3-axis accelerometers; 3-axis gyroscopes; or magnetometers; level sensors; flow sensors; temperature sensors (for example, thermistors); pressure sensors; barometric pressure sensors; gravimeters; altimeters; image capture devices (for example; cameras or lensless apertures); light detection and ranging sensors; proximity sensors (for example, infrared radiation detector and the like); depth sensors; ambient light sensors; ultrasonic transceivers; microphones or other like audio capture devices; etc.

The driver circuitry 1222 may include software and hardware elements that operate to control particular devices that are embedded in the UE 1200, attached to the UE 1200, or otherwise communicatively coupled with the UE 1200. The driver circuitry 1222 may include individual drivers allowing other components to interact with or control various input/output (I/O) devices that may be present within, or connected to, the UE 1200. For example, driver circuitry 1222 may include a display driver to control and allow access to a display device, a touchscreen driver to control and allow access to a touchscreen interface, sensor drivers to obtain sensor readings of sensor circuitry 1220 and control and allow access to sensor circuitry 1220, drivers to obtain actuator positions of electro-mechanic components or control and allow access to the electro-mechanic components, a camera driver to control and allow access to an embedded image capture device, audio drivers to control and allow access to one or more audio devices.

The PMIC 1224 may manage power provided to various components of the UE 1200. In particular, with respect to the processors 1204, the PMIC 1224 may control power-source selection, voltage scaling, battery charging, or DC-to-DC conversion.

In some embodiments, the PMIC 1224 may control, or otherwise be part of, various power saving mechanisms of the UE 1200. For example, if the platform UE is in an RRC_Connected state, where it is still connected to the RAN node as it expects to receive traffic shortly, then it may enter a state known as Discontinuous Reception Mode (DRX) after a period of inactivity. During this state, the UE 1200 may power down for brief intervals of time and thus save power. If there is no data traffic activity for an extended period of time, then the UE 1200 may transition off to an RRC_Idle state, where it disconnects from the network and does not perform operations, such as channel quality feedback, handover, etc. The UE 1200 goes into a very low power state and it performs paging where again it periodically wakes up to listen to the network and then powers down again. The UE 1200 may not receive data in this state; in order to receive data, it must transition back to RRC_Connected state. An additional power saving mode may allow a device to be unavailable to the network for periods longer than a paging interval (ranging from seconds to a few hours). During this time, the device is totally unreachable to the network and may power down completely. Any data sent during this time incurs a large delay and it is assumed the delay is acceptable.

A battery 1228 may power the UE 1200, although in some examples the UE 1200 may be mounted deployed in a fixed location and may have a power supply coupled to an electrical grid. The battery 1228 may be a lithium-ion battery, a metal-air battery, such as a zinc-air battery, an aluminum-air battery, a lithium-air battery, and the like. In some implementations, such as in vehicle-based applications, the battery 1228 may be a typical lead-acid automotive battery.

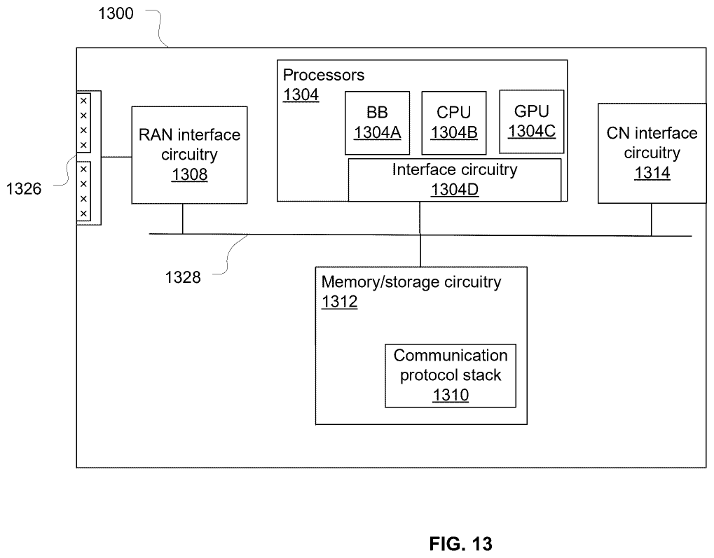

FIG. 13 illustrates a gNB 1300, in accordance with some embodiments. The gNB 1300 may be similar to and substantially interchangeable with the base station 108 of FIG. 1 and other base stations described herein above. Particularly, the gNB 1300 can support polar codes encoding at its transmit chain. The gNB 1300 may also support multi-candidate SCL decoding of polar codes at its receive chain.

The gNB 1300 may include processors 1304, RAN interface circuitry 1308, core network (CN) interface circuitry 1312, and memory/storage circuitry 1316.

The components of the gNB 1300 may be coupled with various other components over one or more interconnects 1328.

The processors 1304, RAN interface circuitry 1308, memory/storage circuitry 1316 (including communication protocol stack 1310), antenna 1350, and interconnects 1328 may be similar to like-named elements shown and described with respect to FIG. 12.

The CN interface circuitry 1312 may provide connectivity to a core network, for example, a Fifth Generation Core network (5GC) using a 5GC-compatible network interface protocol, such as carrier Ethernet protocols, or some other suitable protocol. Network connectivity may be provided to/from the gNB 1300 via a fiber optic or wireless backhaul. The CN interface circuitry 1312 may include one or more dedicated processors or FPGAs to communicate using one or more of the aforementioned protocols. In some implementations, the CN interface circuitry 1312 may include multiple controllers to provide connectivity to other networks using the same or different protocols.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

For one or more embodiments, at least one of the components set forth in one or more of the preceding figures may be configured to perform one or more operations, techniques, processes, or methods as set forth in the example section below. For example, the baseband circuitry as described above in connection with one or more of the preceding figures may be configured to operate in accordance with one or more of the examples set forth below. For another example, circuitry associated with a UE, base station, network element, etc. as described above in connection with one or more of the preceding figures may be configured to operate in accordance with one or more of the examples set forth below in the example section.

### EXAMPLES

In the following sections, further exemplary embodiments are provided.

Example 1 includes a method comprising: receiving a first candidate codeword and a second candidate codeword; decoding the first candidate codeword and the second candidate codeword using a multi-candidate successive cancellation list (SCL) decoder, wherein the SCL decoder uses a binary decision tree; and outputting an output codeword based on the decoding, wherein the output codeword corresponds to the first candidate codeword.

Example 2 includes the method of example 1 or some other example herein, wherein the first and second candidate codewords have a same input and different code configurations.

Example 3 includes the method of example 2 or some other example herein, wherein the decoding includes: extending, in the binary decision tree, a first path associated with the first candidate codeword based on a first frozen bit mapping associated with a first code configuration; and extending, in the binary decision tree contemporaneously with the first path, a second path associated with the second candidate codeword based on a second frozen bit mapping associated with a second code configuration.

Example 4 includes the method of example 1 or some other example herein, wherein the first and second candidate codewords have different inputs and a same code configuration.

Example 5 includes the method of example 1 or some other example herein, wherein the decoding includes pruning one or more paths from the binary decision tree of the multi-candidate SCL decoder based on a blind detection path metric (BDPM), wherein the BDPM is based on a likelihood that the respective paths are included in a set of valid bit sequences.

Example 6 includes the method of example 5 or some other example herein, wherein the BDPM is further based on an input normalization or a difference in code configurations of the first and second candidate codewords.

Example 7 includes the method of example 1 or some other example herein, wherein the decoding includes generating multiple candidate paths via the binary decision tree, wherein the method further comprises performing a cyclic redundancy code (CRC) check on the multiple candidate paths, and wherein the output codeword corresponds to the candidate path that has a best path metric and passes the CRC check.

Example 8 includes the method of example 7 or some other example herein, wherein the candidate paths generated by the decoding do not include any candidate paths associated with the second candidate codeword.

Example 9 includes the method of example 1 or some other example herein, further comprising generating a package of candidate codewords, including the first and second candidate codewords, to be processed by the multi-candidate SCL decoder, wherein the package is generated such that at most one of the candidate codewords in the package is a valid codeword.

Example 10 includes the method of example 1 or some other example herein, wherein the first and second candidate codewords correspond to physical downlink control channel (PDCCH) candidates or physical broadcast channel (PBCH) candidates.

Example 11 includes the method of example 10 or some other example herein, wherein the package of candidate codewords further includes one or more additional candidate codewords.

Example 12 includes an apparatus comprising processing circuitry to: allocate a first physical downlink control channel (PDCCH) candidate and a second PDCCH candidate to a package of PDCCH candidates so that at most one of the PDCCH candidates in the package includes valid downlink control information (DCI); perform multi-candidate successive cancellation list (SCL) decoding on the package of PDCCH candidates with a single SCL decoder that uses a binary decision tree; and output a DCI based on the multi-candidate SCL decoding, wherein the DCI corresponds to the first PDCCH candidate. The apparatus of example 12 may further include interface circuitry coupled to the processing circuitry to enable communication.

Example 13 includes the apparatus of example 12 or some other example herein, wherein the first and second PDCCH candidates have different downlink control information (DCI) formats and a same input.

Example 14 includes the apparatus of example 13 or some other example herein, wherein to perform the multi-candidate SCL decoding includes to: extend, in the binary decision tree, a first path associated with the first PDCCH candidate based on a first frozen bit mapping associated with a first DCI format; and extend, in the binary decision tree in parallel with the extension of the first path, a second path associated with the second PDCCH candidate based on a second frozen bit mapping associated with a second DCI format.

Example 15 includes the apparatus of example 12 or some other example herein, wherein the first and second PDCCH candidates have different inputs and a same downlink control information (DCI) format.

Example 16 includes the apparatus of example 12 or some other example herein, wherein to perform the multi-candidate SCL decoding includes to prune one or more paths from the binary decision tree based on a blind detection path metric (BDPM), wherein the BDPM is based on a likelihood that the respective paths are included in a set of valid bit sequences.

Example 17 includes the apparatus of example 12 or some other example herein, wherein the first PDCCH candidate and the second PDCCH candidate are allocated to the package based on having a same mother code length.

Example 18 includes one or more computer-readable storage media storing instructions that, upon execution by one or more processors, cause operations comprising: receiving a package of candidate codewords; and performing, with a same decoder instance, multi-candidate cyclic redundancy check (CRC)-aided successive cancellation list (CA-SCL) decoding on the package of candidate codewords contemporaneously, wherein the multi-candidate CA-SCL decoding is performed based on a blind detection path metric (BDPM), wherein the BDPM is based on a likelihood that respective decoding paths are included in a set of valid sequences.

Example 19 includes the one or more computer-readable media of example 18 or some other example herein, wherein the package of candidate codewords includes a first physical downlink control channel (PDCCH) or physical broadcast channel (PBCH) candidate and a second PDCCH or PBCH candidate that have different code configurations or different inputs.

Example 20 includes the one or more computer-readable media of example 18 or some other example herein, wherein the operations further comprise allocating the candidate codewords to the package so that at most one of the candidate codewords includes a valid sequence.

Another example may include an apparatus comprising means to perform one or more elements of a method described in or related to any of examples 1-20, or any other method or process described herein.

Another example may include one or more non-transitory computer-readable media comprising instructions to cause an electronic device, upon execution of the instructions by one or more processors of the electronic device, to perform one or more elements of a method described in or related to any of examples 1-20, or any other method or process described herein.

Another example may include an apparatus comprising logic, modules, or circuitry to perform one or more elements of a method described in or related to any of examples 1-20, or any other method or process described herein.

Another example may include a method, technique, or process as described in or related to any of examples 1-20, or portions or parts thereof.

Another example may include an apparatus comprising: one or more processors and one or more computer-readable media comprising instructions that, when executed by the one or more processors, cause the one or more processors to perform the method, techniques, or process as described in or related to any of examples 1-20, or portions thereof.

Another example may include a signal as described in or related to any of examples 1-20, or portions or parts thereof.

Another example may include a datagram, information element, packet, frame, segment, PDU, or message as described in or related to any of examples 1-20, or portions or parts thereof, or otherwise described in the present disclosure.

Another example may include a signal encoded with data as described in or related to any of examples 1-20, or portions or parts thereof, or otherwise described in the present disclosure.

Another example may include a signal encoded with a datagram, IE, packet, frame, segment, PDU, or message as described in or related to any of examples 1-20, or portions or parts thereof, or otherwise described in the present disclosure.

Another example may include an electromagnetic signal carrying computer-readable instructions, wherein execution of the computer-readable instructions by one or more processors is to cause the one or more processors to perform the method, techniques, or process as described in or related to any of examples 1-20, or portions thereof.

Another example may include a computer program comprising instructions, wherein execution of the program by a processing element is to cause the processing element to carry out the method, techniques, or process as described in or related to any of examples 1-20, or portions thereof.

Another example may include a signal in a wireless network as shown and described herein.

Another example may include a method of communicating in a wireless network as shown and described herein.

Another example may include a system for providing wireless communication as shown and described herein.

Another example may include a device for providing wireless communication as shown and described herein.

Any of the above-described examples may be combined with any other example (or combination of examples), unless explicitly stated otherwise. The foregoing description of one or more implementations provides illustration and description but is not intended to be exhaustive or to limit the scope of embodiments to the precise form disclosed. Modifications and variations are possible in light of the above teachings or may be acquired from practice of various embodiments.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method comprising:
receiving a first candidate codeword and a second candidate codeword;
decoding the first candidate codeword and the second candidate codeword using a multi-candidate successive cancellation list (SCL) decoder, wherein the SCL decoder uses a binary decision tree; and
outputting an output codeword based on the decoding, wherein the output codeword corresponds to the first candidate codeword.

2. The method of claim 1, wherein the first and second candidate codewords have a same input and different code configurations.

3. The method of claim 2, wherein the decoding includes:
extending, in the binary decision tree, a first path associated with the first candidate codeword based on a first frozen bit mapping associated with a first code configuration; and
extending, in the binary decision tree contemporaneously with the first path, a second path associated with the second candidate codeword based on a second frozen bit mapping associated with a second code configuration.

4. The method of claim 1, wherein the first and second candidate codewords have different inputs and a same code configuration.

5. The method of claim 1, wherein the decoding includes pruning one or more paths from the binary decision tree of the multi-candidate SCL decoder based on a blind detection path metric (BDPM), wherein the BDPM is based on a likelihood that the respective paths are included in a set of valid bit sequences.

6. The method of claim 5, wherein the BDPM is further based on an input normalization or a difference in code configurations of the first and second candidate codewords.

7. The method of claim 1, wherein the decoding includes generating multiple candidate paths via the binary decision tree, wherein the method further comprises performing a cyclic redundancy code (CRC) check on the multiple candidate paths, and wherein the output codeword corresponds to the candidate path that has a best path metric and passes the CRC check.

8. The method of claim 7, wherein the candidate paths generated by the decoding do not include any candidate paths associated with the second candidate codeword.

9. The method of claim 1, further comprising generating a package of candidate codewords, including the first and second candidate codewords, to be processed by the multi-candidate SCL decoder, wherein the package is generated such that at most one of the candidate codewords in the package is a valid codeword.

10. The method of claim 1, wherein the first and second candidate codewords correspond to physical downlink control channel (PDCCH) candidates or physical broadcast channel (PBCH) candidates.

11. The method of claim 10, wherein the package of candidate codewords further includes one or more additional candidate codewords.

12. An apparatus comprising:
processing circuitry to:
allocate a first physical downlink control channel (PDCCH) candidate and a second PDCCH candidate to a package of PDCCH candidates so that at most one of the PDCCH candidates in the package includes valid downlink control information (DCI);
perform multi-candidate successive cancellation list (SCL) decoding on the package of PDCCH candidates with a single SCL decoder that uses a binary decision tree; and
output a DCI based on the multi-candidate SCL decoding, wherein the DCI corresponds to the first PDCCH candidate; and
interface circuitry coupled to the processing circuitry to enable communication.

13. The apparatus of claim 12, wherein the first and second PDCCH candidates have different downlink control information (DCI) formats and a same input.

14. The apparatus of claim 13, wherein to perform the multi-candidate SCL decoding includes to:
extend, in the binary decision tree, a first path associated with the first PDCCH candidate based on a first frozen bit mapping associated with a first DCI format; and
extend, in the binary decision tree in parallel with the extension of the first path, a second path associated with the second PDCCH candidate based on a second frozen bit mapping associated with a second DCI format.

15. The apparatus of claim 12, wherein the first and second PDCCH candidates have different inputs and a same downlink control information (DCI) format.

16. The apparatus of claim 12, wherein to perform the multi-candidate SCL decoding includes to prune one or more paths from the binary decision tree based on a blind detection path metric (BDPM), wherein the BDPM is based on a likelihood that the respective paths are included in a set of valid bit sequences.

17. The apparatus of claim 12, wherein the first PDCCH candidate and the second PDCCH candidate are allocated to the package based on having a same mother code length.

18. One or more non-transitory, computer-readable storage media storing instructions that, upon execution by one or more processors, cause operations comprising:
receiving a package of candidate codewords; and
performing, with a same decoder instance, multi-candidate cyclic redundancy check (CRC)-aided successive cancellation list (CA-SCL) decoding on the package of candidate codewords contemporaneously, wherein the multi-candidate CA-SCL decoding is performed based on a blind detection path metric (BDPM), wherein the BDPM is based on a likelihood that respective decoding paths are included in a set of valid sequences.

19. The one or more non-transitory, computer-readable media of claim 18, wherein the package of candidate codewords includes a first physical downlink control channel (PDCCH) or physical broadcast channel (PBCH) candidate and a second PDCCH or PBCH candidate that have different code configurations or different inputs.

20. The one or more non-transitory, computer-readable media of claim 18, wherein the operations further comprise allocating the candidate codewords to the package so that at most one of the candidate codewords includes a valid sequence.
